(19) United States
(12) Patent Application Publication
(10) Pub. No.: US 2011/0024726 A1
(43) Pub. Date: Feb. 3, 2011

(54) ORGANIC LIGHT EMITTING DISPLAY DEVICE

(76) Inventors: Sehee LEE, seoul (KR); Sangdae KIM, Daegu (KR); Taeil KUM, Daegu (KR)

Correspondence Address: MORGAN LEWIS & BOCKIUS LLP, 1111 PENNSYLVANIA AVENUE NW, WASHINGTON, DC, 20004, US

(21) Appl. No.: 12/647,938

(22) Filed: Dec. 28, 2009

(30) Foreign Application Priority Data
Jul. 30, 2009 (KR) 10-2009-0070019
Nov. 2, 2009 (KR) 10-2009-0105122

(51) Int. Cl. H01L 51/50; H01L 33/00

(52) U.S. Cl. 257/40; 257/88; 257/79; 257/E51.018

(57) ABSTRACT

An organic light emitting display device includes: a substrate; a first electrode located on the substrate; an organic light emitting layer located on the first electrode; and a second electrode located on the organic light emitting layer, wherein the organic emitting layer comprises an interface buffer layer located on the first electrode and formed from a mixture of an inorganic material and an organic material.

This application claims the benefit of Korean Patent Application No. 10-2009-0070019 filed on Jul. 30, 2009 and 10-2009-0105122 filed on Nov. 2, 2009, which is hereby incorporated by reference.

### BACKGROUND

1. Field

This document relates to an organic light emitting display device.

2. Description of the Related Art

An organic light emitting element used for an organic light emitting display device is a self-light emitting element which has a light emitting layer formed between two electrodes. In the organic light emitting display device, electrons and holes are injected into the light emitting layer, respectively, from a electron injection electrode and a hole injection electrode. The injected electrons and holes are combined to generate excitons, which illuminate when converting from an excited state to a ground state.

Organic light emitting display devices using organic light emitting elements are classified into a top-emission type, a bottom-emission type, and a dual-emission type according to a direction of emitting light. The organic light emitting display devices are also classified into a passive matrix type and an active matrix type according to the driving method thereof.

In these organic light emitting display devices, when scan signals, data signals, and power are supplied to a plurality of subpixels arranged in a matrix, selected subpixels emit light to thus display images.

A subpixel comprises a transistor portion including a switching transistor, a driving transistor, and a capacitor and an organic light emitting diode connected to the driving transistor and comprising a first electrode, an organic light emitting layer, and a second electrode. The organic light emitting layer comprises a common layer for helping the injection and transfer of electrons and holes and a light emitting layer. An organic light emitting diode of a conventional structure has a problem in that a difference in band gap at the interface of a hole transport layer included in the common layer leads to an unbalanced charge, causes degradation in the transportability of the holes, and causes a reduction in the life span of the organic light emitting display device.

### SUMMARY

In one aspect, an organic light emitting display device includes: a substrate; a first electrode located on the substrate; an organic light emitting layer located on the first electrode; and a second electrode located on the organic light emitting layer, wherein the organic emitting layer comprises an interface buffer layer located on the first electrode and formed from a mixture of an inorganic material and an organic material.

In another aspect, an organic light emitting display device includes: a substrate; a first electrode located on the substrate; an organic light emitting layer located on the first electrode; and a second electrode located on the organic light emitting layer, wherein the organic light emitting layer comprises an interface buffer layer formed from an inorganic material and a hole transport material.

### BRIEF DESCRIPTION OF THE DRAWINGS

The accompanying drawings, which are included to provide a further understanding of the invention and are incorporated on and constitute a part of this specification illustrate embodiments of the invention and together with the description serve to explain the principles of the invention.

FIG. 1 is a schematic block diagram of an organic light emitting display device according to a first exemplary embodiment of the present invention;

FIG. 2 is an illustration of a circuit configuration of a subpixel of FIG. 1;

FIG. 3 is a plane view of the organic light emitting display device;

FIG. 4 is a cross-sectional view of area I-II of FIG. 3;

FIG. 5 is a cross-sectional view of the subpixel;

FIG. 6 is a structural view of an organic light emitting layer according to the first exemplary embodiment of the present invention;

FIG. 7 is a partial hierarchy diagram of an organic light emitting diode according to the first exemplary embodiment of the present invention;

FIGS. 8 to 10 are graphs of the life span of the organic light emitting display device for each emission color according to an exemplary embodiment in comparison with a conventional structure;

FIG. 11 is a structural view of an organic light emitting layer according to a second exemplary embodiment of the present invention; and

FIGS. 12 to 17 are graphs of the light intensity and withstand voltage of an organic light emitting display device for each emission color according to an exemplary embodiment in comparison with reference examples.

### DETAILED DESCRIPTION

Reference will now be made in detail embodiments of the invention examples of which are illustrated in the accompanying drawings.

Hereinafter, specific exemplary embodiments of the present invention will be described with reference to the accompanying drawings.

### First Exemplary Embodiment

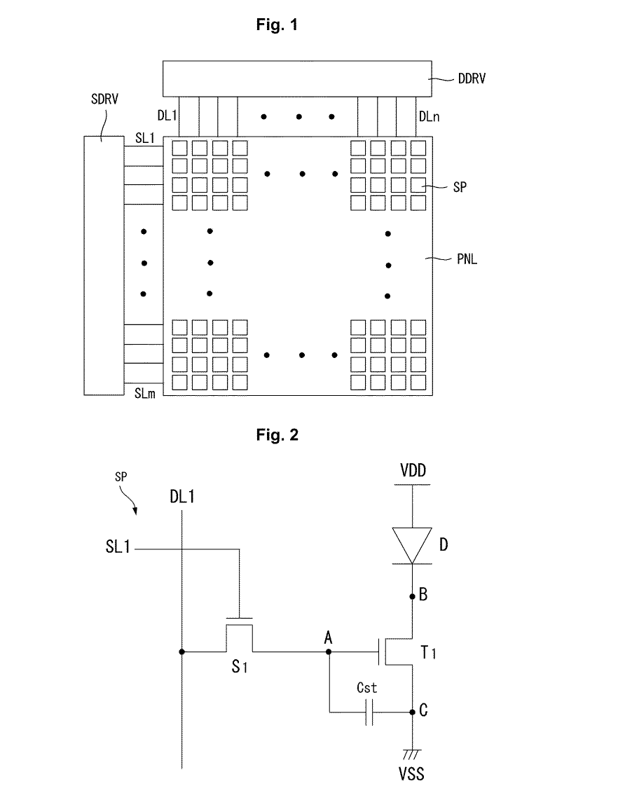

Referring to FIGS. 1 and 2, an organic light emitting display device according to a first exemplary embodiment of the present invention comprises a panel PNL comprising subpixels SP arranged in a matrix, a scan driver SDRV for supplying scan signals to the scan lines SL1 to SLm of the subpixels SP, and a data driver DDRV for supplying data signals to the data lines DL1 to DLn of the subpixels SP.

The subpixels SP are formed in a passive matrix or in an active matrix. If the subpixels SP are formed in the active matrix, they may be configured in a 2T(Transistor)1C(Capacitor) structure comprising a switching transistor S1, a driving transistor T1, a capacitor Cst, and an organic light emitting diode D.

In the 2T1C structure, the elements included in each subpixel SP may be connected as follows. For the switching transistor S1, a gate is connected to the scan line SL1 supplied with a scan signal, one end is connected to the data line DL1 supplied with a data signal, and the other end is connected to a first node A. For the driving transistor T1, a gate is connected to the first node A, one end is connected to a second node B, and the other end is connected to a third node C connected to a second power line VSS supplying a low potential power. For the capacitor Cst, one end is connected to the first node A, and the other end is connected to the third node C. For the organic light emitting diode D, an anode is connected to a first power line VDD supplying a high potential power, and a cathode is connected to the second node B and one end of the driving transistor T1.

While the foregoing description has been made with respect to an example where the transistors S1 and T1 included in the subpixel SP are configured in an N-Type, an exemplary embodiment of the present invention is not limited thereto. The high potential power supplied through the first power line VDD may be higher than the low potential power supplied through the second power line VSS, and the level of power supplied through the first power line VDD and the second power line VSS may be switched according to a driving method.

The above-described subpixel SP may operate as follows. When a scan signal is supplied through the scan line SL1, the switching transistor S1 is turned on. Next, when a data signal supplied through the data line DL1 is supplied to the first node A through the turned-on switching transistor S1, the data signal is stored as a data voltage in the capacitor Cst. Next, when the scan signal is interrupted and the switching transistor S1 is turned off, the driving transistor T1 is driven corresponding to the data voltage stored in the capacitor Cst. Next, when the high potential power supplied through the first power line VDD flows through the second power line VSS, the organic light emitting diode D emits light. However, this is merely an example of the driving method, and an exemplary embodiment of the present invention is not limited thereto.

Hereinafter, the structure of the above-described organic light emitting display device will be described.

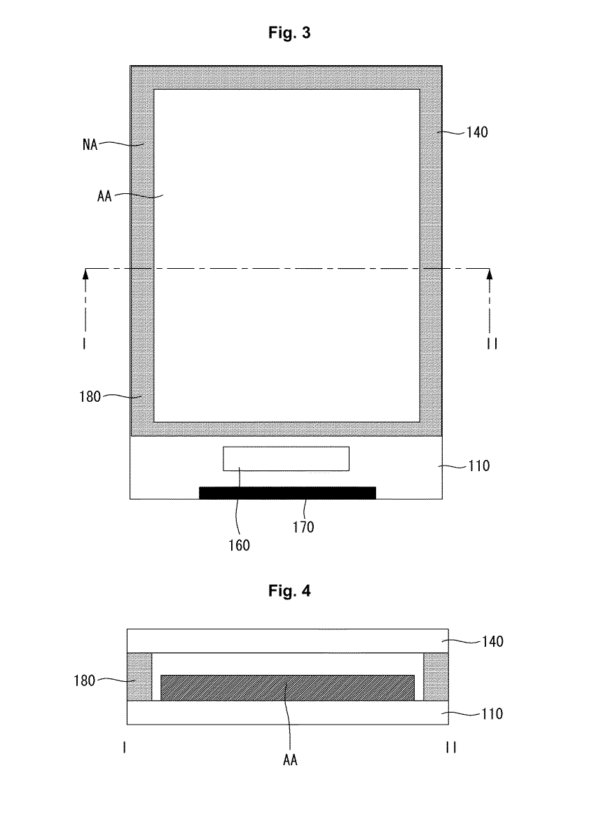

Referring to FIGS. 3 and 4, the organic light emitting display device according to the first exemplary embodiment of the present invention comprises a substrate 110 on which an active area AA is defined by subpixels formed in an active matrix and a sealing substrate 140 for protecting the subpixels formed on the substrate 110 from moisture or oxygen.

The substrate 110 and the sealing substrate 140 are joined and sealed together by an adhesive member 180 formed in a non-display area NA located at the outside of the active area AA. In the illustrated organic light emitting display device, by way of example, a pad portion 170 is provided at the outside of the substrate 110 so as to receive various signals or power from the outside and the elements formed on the substrate 110 and the sealing substrate 140 are driven by a drive unit 160 consisting of a single chip. Here, the drive unit 160 comprises the data driver and the scan driver described in FIG. 1. The above organic light emitting display device according to the first exemplary embodiment of the present invention may be implemented in any one of a top emission type, a bottom emission type, and a dual emission type.

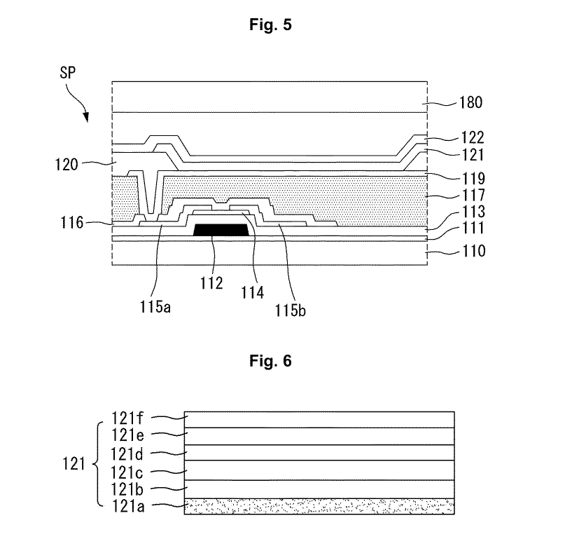

Hereinafter, the structure of the subpixel will be described with reference to FIGS. 5 and 6.

A buffer layer 111 is located on the substrate 110. The buffer layer 111 may be formed in order to protect a thin film transistor, formed in a subsequent process, from impurities such as an alkali ion leaked from the substrate 110. The buffer layer 111 may be formed from silicon oxide (SiO₂), silicon nitride (SiNx), etc.

A gate 112 is located on the buffer layer 111. The gate 112 may be formed of any one selected from the group consisting of molybdenum (Mo), aluminum (Al), chromium (Cr), gold (Au), titanium (Ti), nickel (Ni), neodymium (Nd) and copper (Cu), or an alloy thereof. The gate 112 may be a multilayer formed of any one selected from the group consisting of molybdenum (Mo), aluminum (Al), chromium (Cr), gold (Au), titanium (Ti), nickel (Ni), neodymium (Nd) and copper (Cu), or an alloy thereof. The gate 112 may be a double layer including Mo/Al—Nd or Mo/Al.

A first insulation film 113 is located on the gate 112. The first insulation film 113 may be a silicon oxide film (SiOx), a silicon nitride film (SiNx), or a multilayer thereof, but is not limited thereto.

An active layer 114 is located on the first insulation film 113. The active layer 114 may comprise an amorphous silicon layer or a polycrystalline silicon layer which is formed by crystallizing the amorphous silicon layer. Though not shown, the active layer 114 may comprise a channel region, a source region, and a drain region, and the source region and the drain region may be doped with P-type or N-type impurities. The active layer 114 may further comprise an ohmic contact layer to decrease a contact resistance.

A source 115a and a drain 115b are located on the active layer 114. The source 115a and the drain 115b may be formed of a single layer or a multilayer. When the source 115a and the drain 115b are a single layer, the source 115a and the drain 115b may be formed of any one selected from the group consisting of molybdenum (Mo), aluminum (Al), chromium (Cr), gold (Au), titanium (Ti), nickel (Ni), neodymium (Nd) and copper (Cu), or an alloy thereof. When the source 115a and the drain 115b are a multilayer, the source 115a and the drain 115b may be formed of a double layer including Mo/Al—Nd or a triple layer including Mo/Al/Mo or Mo/Al—Nd/Mo.

A second insulation film 116 is formed on the source 115a and the drain 115b. The second insulation film 116 may be a silicon oxide film (SiOx), a silicon nitride film (SiNx), or a multilayer thereof, but is not limited thereto. The second insulation film 116 may be a passivation film.

A third insulation film 117 is located on the second insulation film 116. The third insulation film 117 may be a silicon oxide film (SiOx), a silicon nitride film (SiNx), or a multilayer thereof, but is not limited thereto. The third insulation film 117 may be a planarization film.

The foregoing is a description of a bottom gate type driving transistor. The following description will be made with respect to an organic light emitting diode located on the driving transistor.

A first electrode 119 is located on the third insulation film 117. The first electrode 119 may serve as an anode or a cathode. The first electrode 119 serving as the anode may comprise a transparent material, such as Indium Tin Oxide (ITO) or Indium Zinc Oxide (IZO), but is not limited thereto.

A bank layer 120 having an aperture region and exposing a part of the first electrode 119 is located on the first electrode 119. The bank layer 120 may comprise an organic material, such as benzocyclobutene (BBC) resin, acryl resin, or polyiide resin, but is not limited thereto.

An organic light emitting layer 121 is located in the aperture region of the bank layer 120. Referring to FIG. 6, the organic light emitting layer 121 comprises an interface buffer layer 121a, a first hole transport layer 121b, a second hole transport layer 121c, a light emitting layer 121d, an electron transport layer 121e, and an electron injection layer 121f. The interface buffer layer 121a functions to facilitate the injection of holes and provide interface stability between the first electrode 119 and the first hole transport layer 121b to thus avoid stress induced during the injection of holes, and is formed from a mixture of an inorganic material and an organic material.

The first hole transport layer 121b and the second hole transport layer 121c function to facilitate the transport of holes, and may be formed from any one or more of NPD(N,N-dinaphthyl-N,N′-diphenyl benzidine), TPD(N,N′-bis-(3-methylphenyl)-N,N′-bis-(phenyl)-benzidine, s-TAD, MTDATA(4,4′,4″-Tris(N-3-methylphenyl-N-phenyl-amino)-triphenyl-amine), and an indenofluorene amine derivative, but is not limited to these materials.

The light emitting layer 121d comprises a host and a dopant. The light emitting layer 121d may be formed of a material capable of emitting red, green, blue and white light, for example, a phosphorescence material or a fluorescence material. In case that the light emitting layer 121d produces red light, the light emitting layer 121d includes a host material including carbazole biphenyl (CBP) or mCP(1,2-bis(carbazol-9-yl). Further, the light emitting layer 121d may be formed of a phosphorescence material including a dopant material including at least one selected from the group consisting of PIQIr(acac)(bis(I-phenylisoquinoline)acetylacetonate iridium), PQIr(acac)(bis(1-phenylquinoline)acetylacetonate iridium), PQIr(tris(1-phenylquinoline)iridium) and PtOEP(octaethylporphyrin platinum) or a fluorescence material including PBD:Eu(DBM)3(Phen) or Perylene, but is not limited thereto. In case that the light emitting layer 121d produces green light, the light emitting layer 121d includes a host material including CBP or mCP. Further, the light emitting layer 120d may be formed of a phosphorescence material including a dopant material including Ir(ppy)3(fac tris(2-phenylpyridine)iridium) or a fluorescence material including Alq3(tris(8-hydroxyquinolino)aluminum), but is not limited thereto. In case that the light emitting layer 121d produces blue light, the light emitting layer 121d includes a host material including CBP or mCP. Further, the light emitting layer 121d may be formed of a phosphorescence material including a dopant material including (4,6-F2ppy)2Irpic. Alternatively, the light emitting layer 121d may be formed of a fluorescence material including any one selected from the group consisting of spiro-DPVBi, spiro-6P, distyryl-benzene (DSB), distyryl-arylene (DSA), PFO-based polymers, and PPV-based polymers, but is not limited thereto.

The electron transport layer 120e functions to facilitate the transportation of electrons, and may be formed of at least one selected from the group consisting of Alq3(tris(8-hydroxyquinolino)aluminum, PBD, TAZ, spiro-PBD, BAlq, and SAlq, but is not limited thereto.

The electron injection layer 121f functions to facilitate the injection of electrons, and may be formed of Alq3(tris(8-hydroxyquinolino)aluminum), PBD, TAZ, Spiro-PBD, BAlq or SAlq, but is not limited thereto. An exemplary embodiment of the present invention is not limited to FIG. 6, and at least one of the first hole transport layer 121b, the second hole transport layer 121c, the electron transport layer 121e, and the electron injection layer 121f may be omitted.

A second electrode 122 is located on the organic light emitting layer 121. The second electrode 122 may serve as a cathode or an anode. The second electrode 122 serving as the cathode may comprise aluminum (Al), but is not limited thereto.

Hereinafter, a test example of an organic light emitting diode according to the first exemplary embodiment of the present invention will be described.

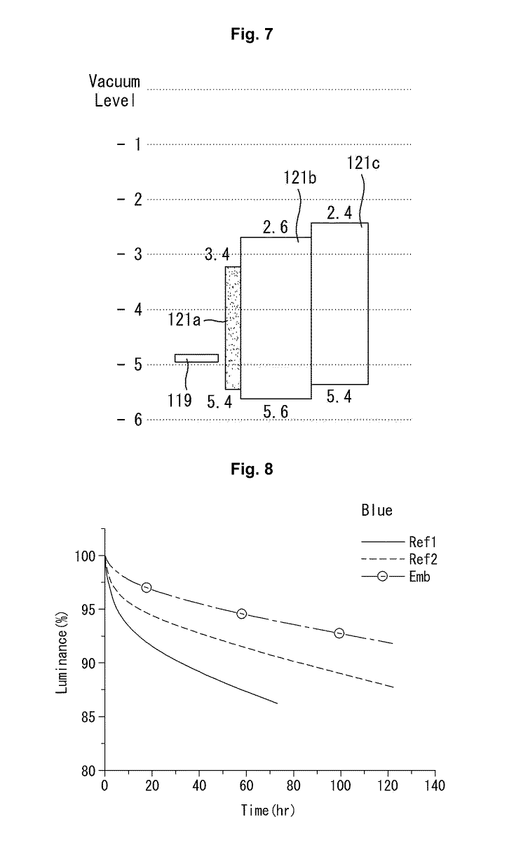

Referring to FIG. 7, the organic light emitting diode implemented according to the first exemplary embodiment of the present invention comprises an interface buffer layer 121a located between the first electrode 119 serving as the anode and the second electrode 122 serving as the cathode, a first hole transport layer 121b, a second hole transport layer 121c, a light emitting layer 121d, an electron transport layer 121e, and an electron injection layer 121f.

The following Table 1 shows voltages V, light intensities (cd/A), currents (Im/W), and color coordinates (CIE_x, XIE_y) which were measured in conventional structures and the structure of the exemplary embodiment.

In Table 1, “BUFFER” represents the interface buffer layer 121a, “HIL” represents a hole injection layer, “HTL1” represents the first hole transport layer 121b, and “HTL2” represents the second hole transport layer 121c. Besides, “-” represents none.

TABLE 1

| | | | | | | Optical Properties | | | | |
|---|---|---|---|---|---|---|---|---|---|---|
| Structure | BUFFER | HIL | HTL1 | HTL2 | color | v | Cd/A | Im/W | CIE/x | CI/E_y |
| Ref 1 | — | 50 Å | — | 1000 Å | Red | 3.1 | 16.1 | 16.5 | 0.670 | 0.328 |
| | | | | | Green | 2.9 | 27.2 | 29.3 | 0.222 | 0.685 |
| | | | | 700 Å | Blue | 3.2 | 4.3 | 4.2 | 0.144 | 0.073 |
| Ref 2 | — | 50 Å | 500Å | 600 Å | Red | 3.1 | 15.6 | 15.8 | 0.670 | 0.327 |
| | | | | | Green | 2.9 | 25.2 | 27.3 | 0.226 | 0.689 |
| | | | | 200 Å | Blue | 3.2 | 4.1 | 4.0 | 0.142 | 0.077 |
| Emb | 50 Å | — | — | 600 Å | Red | 3.0 | 18.0 | 18.6 | 0.668 | 0.329 |
| | | | | | Green | 3.0 | 30.3 | 32.2 | 0.230 | 0.687 |
| | | | | 200 Å | Blue | 3.3 | 4.8 | 4.6 | 0.142 | 0.078 |

In the test example of Table 1, by way of example, the interface buffer layer 121a is formed from an inorganic material, which is magnesium fluoride (MgF2), and an organic material, which is rubrene (5,6,11,12-tetraphenylnapthacene) as an orange dopant. The first hole transport layer 121b is formed from an indenofluorene amine compound which is a derivative, for example. The second hole transport layer 121c is formed from NPD which is an aromatic amine, for example. Here, schematic conditions of each layer located between the first electrode 119 and the second electrode 122 are as in Table 1.

In the organic light emitting diode according to the exemplary embodiment, the interface buffer layer 121a formed from a mixture of an inorganic material and an organic material is interposed between the first electrode 119 and the first hole transport layer 121b. The interface buffer layer 121a functions as a deterioration preventing layer which avoids stress induced during the injection of holes by facilitating the injection of holes and providing interface stability between the first electrode 119 and the first hole transport layer 121b. More specifically, the interface buffer layer 121a functions to activate (stabilize) the interface of the first electrode 119 damaged due to a problem occurring during plasma treatment on the first electrode 119 or a problem caused by a contaminant source.

The thickness of the interface buffer layer 121a may range from 10 Å to 300 Å, and the inorganic material and the organic material may have a mixing ratio of 10:1 to 1:10. Preferably, the thickness of the interface buffer layer 121a ranges from 50 Å to 100 Å, and the inorganic material and the organic material may have a mixing ratio of 1:3 to 5. In the formation of the interface buffer layer 121a, the content of the organic material may be 3 to 5 times more than that of the inorganic material. However, if the content of the inorganic material is equal to or greater than that of the inorganic material, the properties of the buffer may be lost due to the excessive content of the inorganic material and interfacial activation with the first electrode 119 may be degraded. Also, if the content of the organic material is greater than 3 to 5 times that of the inorganic material, interfacial activation may be degraded. Here, if the thickness of the interface buffer layer 121a is greater than 50 Å, this activates the interface with the first electrode 119 and facilitates the injection of holes. On the contrary, if the thickness of the interface buffer layer 121a is less than 100 Å, this prevents a rise in driving voltage, activates the interface with the first electrode 119, and facilitates the injection of holes.

The first hole transport layer 121b adjacent to the interface buffer layer 121a is configured to be at a lower level than the HOMO of the second hole transport layer 121c. The second hole transport layer 121c adjacent to the first hole transport layer 121b is configured to be at a higher level than the LUMO of the first hole transport layer 121b. However, the absolute values of the HOMO and LUMO levels of the first hole transport layer 121b should have a difference of at least 0.1 eV from the absolute values of the HOMO and LUMO levels of the second hole transport layer 121c. For example, in a case where the HOMO level of the second hole transport layer 121c is 2.4 eV and the LUMO level thereof is 5.4 eV, the HOMO level of the first hole transport layer 121b may be set to 2.6 eV and the LUMO level thereof may be set to 5.6 eV (level difference is set to 0.2 eV).

By configuring the interface buffer layer 121a, the first hole transport layer 121b, and the second hole transport layer 121c under the same condition as the exemplary embodiment, the hole injection properties are enhanced by the interface buffer layer 121a and the barrier between the first hole transport layer 121b and the second hole transport layer 121c can be lowered. More specifically, the interface buffer layer 121a can enhance the hole injection properties. And, the first hole transport layer 121b can rapidly transport the holes injected through the interface buffer layer 121a. Moreover, the second hole transport layer 121c functions as a blocking layer for blocking holes, and therefore a charge balance is well established, thereby maximizing an increase in the life span of the elements.

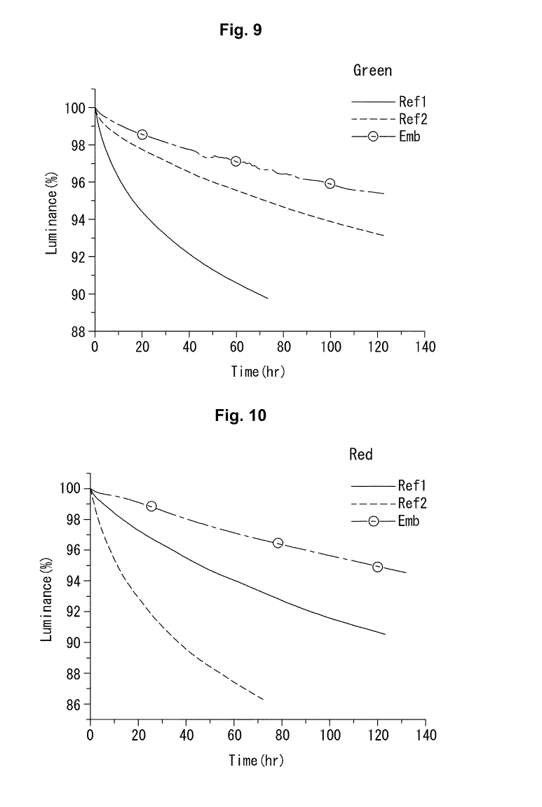

Referring to the above Table 1, it can be seen that, in terms of optical properties, an element realized as an organic light emitting diode according to the exemplary embodiment shows improved properties compared to the optical properties of Reference Examples 1 and 2. Moreover, referring to FIGS. 8 and 9, it can be seen that red, blue, and green elements implemented in the exemplary embodiment are considerably improved in the optical properties and in the life span properties compared to the life span properties of Reference Examples 1 and 2.

As seen above, the present invention can provide an organic light emitting display device, which can improve the life span of an element by interposing an interface buffer layer between a first electrode and an adjacent hole transport layer, the interface buffer layer functioning as a deterioration preventing layer which avoids stress induced during the injection of holes by facilitating the injection of holes and providing interface stability between the first electrode and the adjacent hole transport layer. Furthermore, the element according to the present invention can improve its optical properties and its initial life span extending property which influences an afterimage among all the life span properties.

### Second Exemplary Embodiment

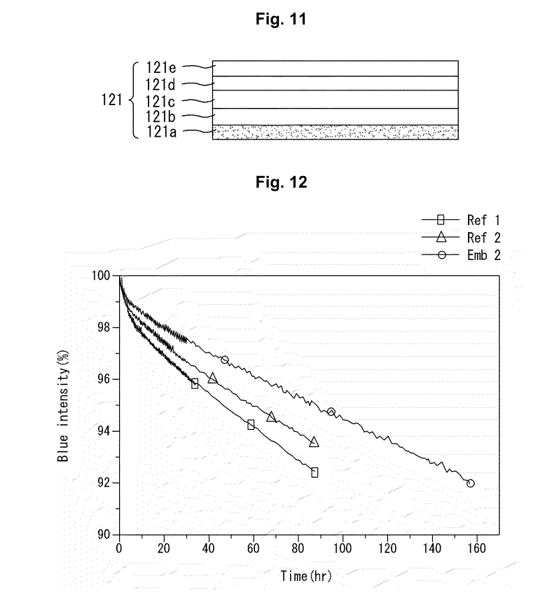

A subpixel according to a second exemplary embodiment of the present invention has a similar structure to that of FIG. 5 except that an organic light emitting layer comprises, as shown in FIG. 11, an interface buffer layer 121a, a hole transport layer 121b, an emitting layer 121b, an electron transport layer 121d, and an electron injection layer 121e.

The interface buffer layer 121a functions to facilitate the injection of holes and is located between the first electrode 119 and the hole transport layer 121b to provide interface stability therebetween. The interface buffer layer 121a may function to avoid stress induced during the injection of holes, and is formed from a mixture of an inorganic material and an organic material. The inorganic material may be formed of any one selected from the group consisting of LiF, NaF, KF, RbF, CsF, FrF, and MgF2 or any one selected from the group consisting of Li2O, Na2O, K2O, BeO, MgO, CaO, B2O3, Al2O3, and SiO2. The organic material may be formed of a hole transport material, which is the same material as the hole transport layer 121b.

The hole transport layer 121b functions to facilitate the transport of holes, and may be formed from any one of NPD(N,N-dinaphthyl-N,N′-diphenyl benzidine), TPD(N,N′-bis-(3-methylphenyl)-N,N′-bis-(phenyl)-benzidine, s-TAD, MTDATA(4,4′,4″-Tris(N-3-methylphenyl-N-phenyl-amino)-triphenyl-amine), an aromatic amine derivative, a fluorine derivative, and an anthracene derivative. The hole transport layer 12b may consist of two layers.

The light emitting layer 121c comprises a host and a dopant. The light emitting layer 121c may be formed of a material capable of emitting red, green, blue and white light, for example, a phosphorescence material or a fluorescence material. In case that the light emitting layer 121c produces red light, the light emitting layer 121c includes a host material including carbazole biphenyl (CBP) or mCP(1,2-bis(carbazol-9-yl). Further, the light emitting layer 121c may be formed of a phosphorescence material including a dopant material including at least one selected from the group consisting of PIQIr(acac)(bis(I-phenylisoquinoline)acetylacetonate iridium), PQIr(acac)(bis(1-phenylquinoline)acetylacetonate iridium), PQIr(tris(1-phenylquinoline)iridium) and PtOEP(octaethylporphyrin platinum) or a fluorescence material including PBD:Eu(DBM)3(Phen) or Perylene, but is not limited thereto. In case that the light emitting layer 121c produces green light, the light emitting layer 121c includes a host material including CBP or mCP. Further, the light emitting layer 120c may be formed of a phosphorescence material including a dopant material including Ir(ppy)3(fac tris(2-phenylpyridine)iridium) or a fluorescence material including Alq3(tris(8-hydroxyquinolino)aluminum), but is not limited thereto. In case that the light emitting layer 121c produces blue light, the light emitting layer 121c includes a host material including CBP or mCP. Further, the light emitting layer 121c may be formed of a phosphorescence material including a dopant material including (4,6-F2ppy)2Irpic. Alternatively, the light emitting layer 121c may be formed of a fluorescence material including any one selected from the group consisting of spiro-DPVBi, spiro-6P, distyryl-benzene (DSB), distyryl-arylene (DSA), PFO-based polymers, and PPV-based polymers, but is not limited thereto.

The electron transport layer 120d functions to facilitate the transportation of electrons, and may be formed of at least one selected from the group consisting of Alq3(tris(8-hydroxyquinolino)aluminum, PBD, TAZ, spiro-PBD, BAlq, and SAlq, but is not limited thereto.

The electron injection layer 121e functions to facilitate the injection of electrons, and may be formed of Alq3(tris(8-hydroxyquinolino)aluminum), PBD, TAZ, Spiro-PBD, BAlq or SAlq, but is not limited thereto. The exemplary embodiment of the present invention is not limited to FIG. 6, and at least one of the hole transport layer 121b, the electron transport layer 121d, and the electron injection layer 121e may be omitted.

Hereinafter, a test example of an organic light emitting diode according to a second exemplary embodiment of the present invention will be described.

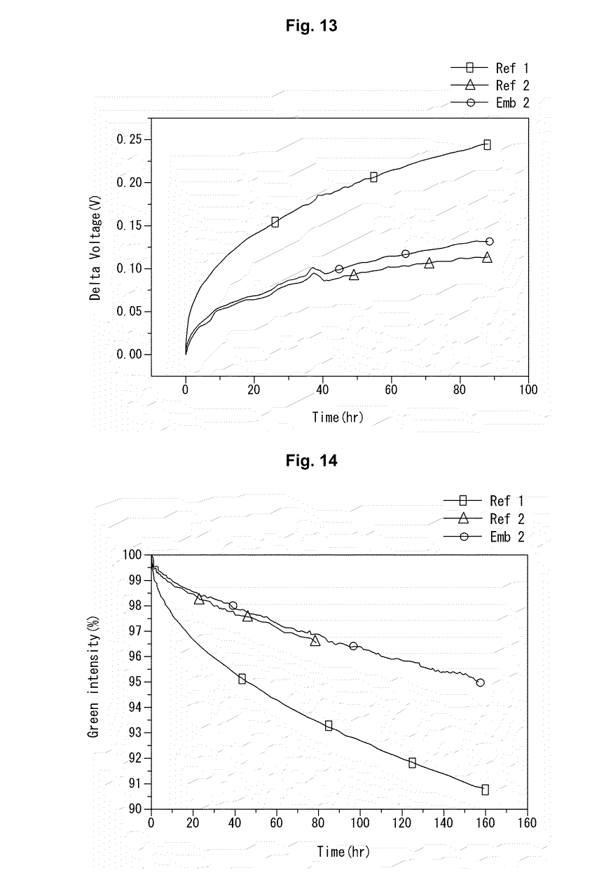

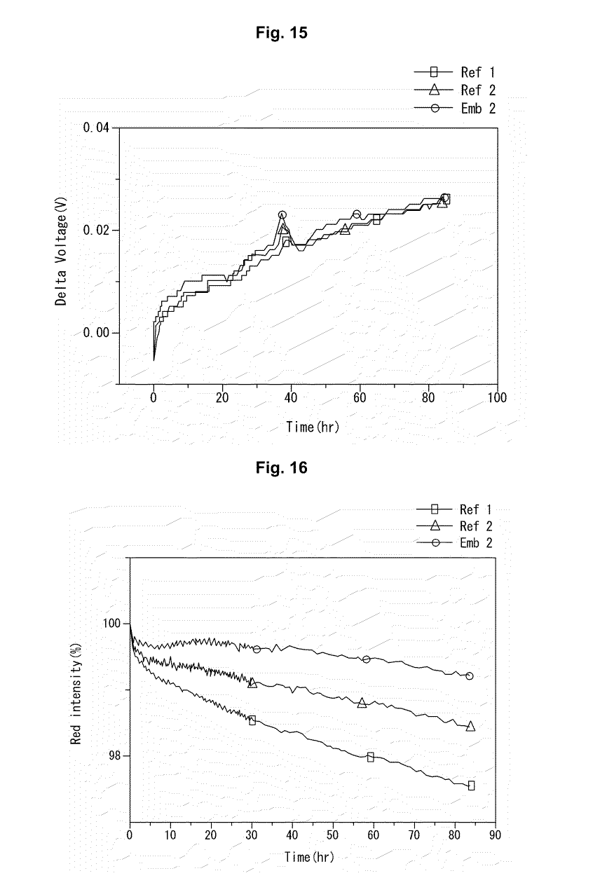

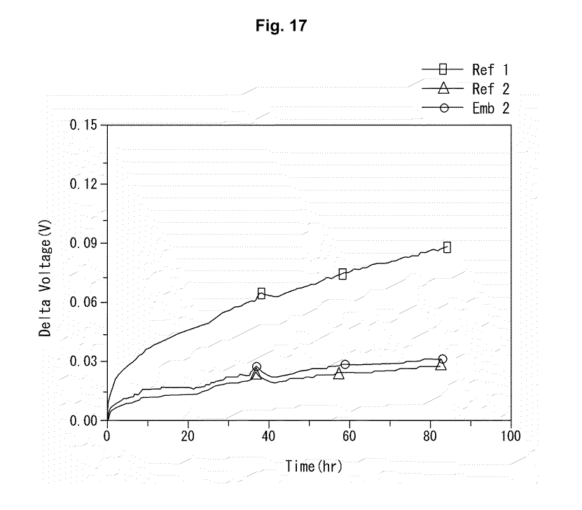

FIGS. 12 to 17 are graphs of the light intensity and withstand voltage of an organic light emitting display device for each emission color according to an exemplary embodiment in comparison with reference examples.

Referring to FIG. 11, the organic light emitting diode implemented according to the second exemplary embodiment of the present invention comprises an interface buffer layer 121a located between the first electrode 119 serving as the anode and the second electrode 122 serving as the cathode, a hole transport layer 121b, a light emitting layer 121c, an electron transport layer 121d, and an electron injection layer 121e. The structures of Reference Examples 1 and 2 are identical to the structure of the exemplary embodiment except for the presence and absence of an interface buffer layer and a hole injection layer.

The following Table 2 shows voltages V, light intensities (cd/A), currents (Im/W), and color coordinates (CIE_x, XIE_y) which were measured in the structures of the reference examples and the structure of the exemplary embodiment. In Table 1, “BUFFER” represents the interface buffer layer 121a, “HIL” represents a hole injection layer, and “HTL” represents the hole transport layer 121b. Besides, “-” represents none.

TABLE 2

| | | | | | Optical Properties | | | | |
|---|---|---|---|---|---|---|---|---|---|
| Structure | BUFFER | HIL | HTL | color | v | Cd/A | Im/W | CIE/x | CI/E_y |
| Ref 1 | — | 100 Å | 1100 Å | Red | 3.3 | 15.1 | 14.6 | 0.679 | 0.319 |
| | | | | Green | 3.2 | 26.3 | 26.0 | 0.274 | 0.657 |
| | | | 700 Å | Blue | 3.5 | 4.5 | 4.1 | 0.142 | 0.126 |
| Ref 2 | 50 Å | 100 Å | 1100 Å | Red | 3.1 | 14.7 | 14.7 | 0.679 | 0.319 |
| | | | | Green | 3.1 | 26.0 | 26.3 | 0.275 | 0.657 |
| | | | 700 Å | Blue | 3.3 | 4.4 | 4.1 | 0.142 | 0.126 |
| Emb 2 | 50 Å | — | 1100 Å | Red | 3.1 | 15.2 | 15.3 | 0.678 | 0.319 |
| | | | | Green | 3.1 | 28.7 | 26.2 | 0.273 | 0.658 |
| | | | 700 Å | Blue | 3.3 | 4.3 | 4.1 | 0.142 | 0.127 |

In the test example of Table 2, by way of example, the interface buffer layer 121a is formed from an inorganic material, which is magnesium fluoride (MgF2), and an organic material, which is formed from NPD which is an aromatic amine. Here, schematic conditions of each layer located between the first electrode 119 and the second electrode 122 are as shown in Table 2 and as stated above.

Referring to the above Table 2, it can be seen that, in terms of optical properties, an element realized as an organic light emitting diode according to the second exemplary embodiment shows improvement in terms of optical properties in comparison with Reference Examples 1 and 2. Moreover, referring to FIGS. 12 to 17, it can be seen that red, blue, and green elements implemented in the second exemplary embodiment show stability in withstand voltage characteristic as well as improvement in intensity in comparison with Reference Examples 1 and 2.

In the organic light emitting diode according to the second exemplary embodiment, the interface buffer layer 121a formed from a mixture of an inorganic material and an organic material, which is the same material as the hole transport layer, is interposed between the first electrode 119 and the first hole transport layer 121b. The interface buffer layer 121a functions as a deterioration preventing layer which avoids stress induced during the injection of holes by facilitating the injection of holes and providing interface stability between the first electrode 119 and the first hole transport layer 121b. More specifically, the interface buffer layer 121a functions to activate (stabilize) the interface of the first electrode 119 damaged due to a problem occurring during plasma treatment on the first electrode 119 or a problem caused by a contaminant source. The interface buffer layer 121a of the second exemplary embodiment has a structure where an organic material, which is the same material as the hole transport layer, is mixed with an inorganic material, and hence the number of deposition chambers does not have to be increased in order to mix the organic material. Therefore, the second exemplary embodiment can avoid process defects or an increase in manufacturing time which result from the transfer of a chamber and the additional deposition of an organic material during the formation of the interface buffer layer 121a.

The thickness of the interface buffer layer 121a may range from 5 Å to 300 Å, and the inorganic material and the organic material may have a mixing ratio of 10:1 to 1:10. Preferably, the thickness of the interface buffer layer 121a ranges from 20 Å to 100 Å, and the inorganic material and the organic material may have a mixing ratio of 1:3 to 5.

In the formation of the interface buffer layer 121a, the content of the organic material may be 3 to 5 times more than that of the inorganic material. However, if the content of the inorganic material is equal to or less than that of the inorganic material, it is possible to prevent the loss of the properties of the buffer due to the content of the inorganic material and prevent degradation in interfacial activation with the first electrode 119. Also, if the content of the organic material is less than 3 to 5 times that of the inorganic material, an interfacial activation function may be performed. More specifically, the functions and effects of the interface buffer layer 121a depending on the ratio of the inorganic material to the organic material are as follows: (1) if the ratio of the inorganic material to the organic material is 1:1, an increase in turn-on voltage, a reduction in efficiency, excellent withstand voltage, and longer life span can be shown in comparison with Reference Examples 1 and 2; and (2) if the ratio of the inorganic material to the organic material is 1:3, an equal turn-on voltage, an equal efficiency, excellent withstand voltage, and longer life span can be shown in comparison with Reference Examples 1 and 2. (3) if the ratio of the inorganic material to the organic material is 1:5, an equal turn-on voltage, an equal efficiency, excellent withstand voltage, and longer life span are shown in comparison with Reference Examples 1 and 2 but the degree of improvement is small in comparison with the structure of (2). Therefore, in the formation of the interface buffer layer 121a, if the ratio of the inorganic material increases, the power consumption reduction effect may be degraded due to an increase in turn-on voltage. On the other hand, if the thickness of the interface buffer layer 121a is greater than 20 Å, this activates the interface with the first electrode 119, facilitates the injection of holes, and stabilizes the withstand voltage. On the contrary, if the thickness of the interface buffer layer 121a is less than 100 Å, this prevents a rise in driving voltage, activates the interface with the first electrode 119, facilitates the injection of holes, and stabilizes the withstand voltage. By configuring the interface buffer layer 121a between the first electrode 119 and the hole transport layer 121b under the same condition as the second exemplary embodiment, the hole injection properties are enhanced by the interface buffer layer 121a, and the withstand voltage can be stabilized.

As seen above, the second exemplary embodiment of the present invention can provide an organic light emitting display device, which can stabilize withstand voltage and improve the life span of an element by interposing an interface buffer layer between a first electrode and an adjacent hole transport layer, the interface buffer layer functioning as a deterioration preventing layer which avoids stress induced during the injection of holes by facilitating the injection of holes and providing interface stability between the first electrode and the adjacent hole transport layer. Furthermore, the element according to the present invention can improve its optical properties and its initial life span extending property which influences an afterimage among all the life span properties.

The foregoing embodiments and advantages are merely exemplary and are not to be construed as limiting the present invention. The present teaching can be readily applied to other types of apparatuses. The description of the present invention is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures. Moreover, unless the term “means” is explicitly recited in a limitation of the claims, such as limitation is not intended to be interpreted under 35 USC 112 (6).

What is claimed is:

1. An organic light emitting display device comprising:
a substrate;
a first electrode located on the substrate;
an organic light emitting layer located on the first electrode; and
a second electrode located on the organic light emitting layer,
wherein the organic emitting layer comprises an interface buffer layer located on the first electrode and formed from a mixture of an inorganic material and an organic material.

2. The organic light emitting display device of claim 1, wherein the organic material is an orange dopant.

3. The organic light emitting display device of claim 1, wherein the thickness of the interface buffer layer ranges from 10 Å to 300 Å.

4. The organic light emitting display device of claim 1, wherein the thickness of the interface buffer layer ranges from 50 Å to 100 Å.

5. The organic light emitting display device of claim 4, wherein the interface buffer layer has a mixing ratio of 1:3 to 5 between the inorganic material and the organic material.

6. The organic light emitting display device of claim 1, wherein the organic light emitting layer comprises:
a first hole transport layer located on the interface buffer layer;
a second hole transport layer located on the first hole transport layer;
a light emitting layer located on the second hole transport layer;
an electron transport layer located on the light emitting layer; and
an electron injection layer located on the electron transport layer.

7. The organic light emitting display device of claim 6, wherein the LUMO of the second hole transport layer is at a higher level than the LUMO of the first hole transport layer.

8. The organic light emitting display device of claim 6, wherein the HOMO of the first hole transport layer is at a lower level than the HOMO of the second hole transport layer.

9. The organic light emitting display device of claim 6, wherein the absolute values of the HOMO and LUMO levels of the first hole transport layer have a difference of at least 0.1 eV from the absolute values of the HOMO and LUMO levels of the second hole transport layer.

10. The organic light emitting display device of claim 6, wherein the first hole transport layer is an indenofluorene amine derivative.

11. An organic light emitting display device comprising:
a substrate;
a first electrode located on the substrate;
an organic light emitting layer located on the first electrode; and
a second electrode located on the organic light emitting layer,
wherein the organic emitting layer comprises an interface buffer layer formed from an inorganic material and a hole transport material.

12. The organic light emitting display device of claim 11, wherein the interface buffer layer is located between a hole transport layer and the first electrode.

13. The organic light emitting display device of claim 11, wherein the hole transport material is the same material as the hole transport layer included in the organic light emitting layer.

14. The organic light emitting display device of claim 11, wherein the organic material and the hole transport material have a mixing ratio of 1:3 to 5.

15. The organic light emitting display device of claim 11, wherein the inorganic material is formed of any one selected from the group consisting of LiF, NaF, KF, RbF, CsF, FrF, and MgF2 or any one selected from the group consisting of Li2O, Na2O, K2O, BeO, MgO, CaO, B2O3, Al2O3, and SiO2.

16. The organic light emitting display device of claim 11, wherein the hole transport layer is formed from any one of an aromatic amine derivative, a fluorine derivative, and an anthracene derivative.

17. The organic light emitting display device of claim 11, wherein the thickness of the interface buffer layer ranges from 5 Å to 300 Å.

18. The organic light emitting display device of claim 11, wherein, the thickness of the interface buffer layer ranges from 20 Å to 100 Å.

19. The organic light emitting display device of claim 11, wherein the organic light emitting layer comprises:
a hole transport layer located on the interface buffer layer;
a light emitting layer located on the second hole transport layer;
an electron transport layer located on the light emitting layer; and
an electron injection layer located on the electron transport layer.
